(19) United States
(12) Patent Application Publication
(10) Pub. No.: US 2022/0342634 A1
(43) Pub. Date: Oct. 27, 2022

(54) COMPACT, HIGH PERFORMANCE FULL ADDERS

(71) Applicant: TEXAS INSTRUMENTS INCORPORATED, Dallas, TX (US)

(72) Inventors: Arnab Khawas, Bangalore (IN); Nandini Bollam, Bangalore (IN); Badarish Mohan Subbannavar, Bangalore (IN)

(21) Appl. No.: 17/241,753

(22) Filed: Apr. 27, 2021

(51) Int. Cl. G06F 7/501; H03K 17/687

(52) U.S. Cl. CPC G06F 7/501; H03K 17/6872

(57) ABSTRACT

Examples of compact, high performance full adder circuits and methods of forming and operating the same are provided. In an example, a full adder comprises a first stage, a second stage and a third stage. The first stage has a first output at which a first reused signal is generated and a second output at which a second reused signal is generated. The second stage has a first reused signal input to which the first reused signal is applied, a second reused signal input to which the second reused signal is applied, and a sum output at which a sum signal is generated. The third stage has a third reused signal input to which the first reused signal is applied, a fourth reused signal input to which the second reused signal is applied, and a carry-out output at which a carry-out signal is generated. In some examples, the first stage includes a transistor stack and an inverter that share a transistor.

### FIELD OF DISCLOSURE

This disclosure relates generally to full adder circuits, and more particularly to compact, high performance full adder circuits.

### BACKGROUND

An adder circuit, and in particular a full adder circuit, is an important building block for any digital design. A full adder is so named because it adds two binary values plus a carry-in value to produce a sum and carry-out values. A full adder circuit is central to digital circuits that perform addition. For example, full adders are used in the implementation of a multiplier, many of which are aggregated in any data computation component.

Considering that most digital circuit arrangements employ multiple full adders, the area on a semiconductor substrate that a full adder occupies (i.e., its footprint) and its performance are important design considerations. In an existing complementary metal-oxide-silicon field effect transistor (CMOS—including a p-channel metal-oxide-silicon field effect transistor (PMOS) and an n-channel metal-oxide-silicon field effect transistor (NMOS)) full adder implementation, the sum (s) and carry-out (co) are implemented in such a way that computation of the sum (s) is dependent on computation of the carry-out (co). This increases the number of transistors receiving the primary inputs, i.e., inputs a, b and carry-in (ci), which in turn increases input capacitance. Higher transistor count and input capacitance leads to higher power consumption, as well as higher delays in computation and transmission. A solution to these issues is desirable.

### SUMMARY

In accordance with an example, an adder comprises a first stage, a second stage, and a third stage. The first stage has a first reused signal output and a second reused signal output. The second stage has a first reused signal input coupled to the first reused signal output, a second reused signal input coupled to the second reused signal output, and a sum signal output. The third stage has a third reused signal input coupled to the first reused signal output, a fourth reused signal input coupled to the second reused signal output, and a carry-out signal output.

In accordance with an example, an adder comprises first, second and third stages. The first stage includes a transistor stack and an inverter coupled to the transistor stack and configured to share a transistor. The first stage generates a plurality of signals. The second stage is coupled to the first stage and has a sum output at which a sum signal (s) is generated based in part on the plurality of signals generated in the first stage. The third stage is coupled to the first stage and has a carry-out output at which a carry-out signal (co) is generated based in part on the plurality of signals generated in the first stage.

In accordance with an example, a method comprises applying a carry-in signal (ci), a carry-in complement signal (cz), a first primary input signal (b), and a first primary input complement signal (bz) as inputs to a first stage of an adder to generate first and second reused signals; applying the first and second reused signals to a second stage of the adder, the second stage generating a sum signal (s); and applying the first and second reused signals as inputs to a third stage of the adder, the third stage generating a carry-out signal (co).

In accordance with an example, a method of generating a sum signal and a carry-out signal comprises generating, by a first stage of an adder, a first reused signal and a second reused signal in response to a carry-in input signal, a carry-in complement input signal, a first primary input signal and a first primary input complement signal; generating, by a second stage of the adder, a sum signal in response to receiving the first reused signal and the second reused signal; and generating, by a third stage of the adder, a carry-out signal in response to receiving the first reused signal and the second reused signal.

These and other features will be better understood from the following detailed description with reference to the accompanying drawings.

### BRIEF DESCRIPTION OF THE DRAWINGS

Features of the disclosure may be understood from the following figures taken in conjunction with the detailed description.

FIG. 1 is a circuit diagram of an example full adder.

FIGS. 2A, 2B, 2C and 2D are circuit diagrams illustrating example steps in forming a stage of a full adder utilizing transistor sharing.

FIG. 3 is a flow diagram of an example of operating a full adder.

The same reference numbers are used in the drawings to designate the same or similar (structurally and/or functionally) features.

### DETAILED DESCRIPTION

Specific examples are described below in detail with reference to the accompanying figures. These examples are not intended to be limiting. In the drawings, corresponding numerals and symbols generally refer to corresponding parts unless otherwise indicated. The objects depicted in the drawings are not necessarily drawn to scale.

In the following description, the primary inputs are denoted a, b and ci, the latter of which represents the carry-in input. The complements or inverses of a, b and ci are denoted az, bz and cz, respectively. The carry-out output is denoted co, and the sum output is denoted s.

In example arrangements, a compact, high performance full adder is provided. In some examples, the full adder employs less transistors than existing full adders. In some examples, the full adder reuses internally generated logic signals, e.g., b(XNOR)ci and b(XOR)ci, to generate both the sum signal (s) and the carry-out signal (co), which represent the sum and carry-out values, respectively. That is, b(XNOR)ci and b(XOR)ci can be used in combination with primary inputs, e.g., a, b and ci, to generate both the sum and carry-out signals/values. In some examples, a transistor sharing technique is implemented in which a transistor is shared among two functional circuit components. In one implementation, a transistor is shared between an inverter for one of the primary inputs, e.g., b, and a transistor stack that outputs one of the reused signals, e.g., b(XNOR)ci. In some examples, the number of transistors receiving primary input signals/values is reduced relative to existing implementations. Example full adder arrangements provide advantages in terms of reduced area occupancy, i.e., reduced footprint, lower input capacitance, lower power consumption, and faster signal transmission.

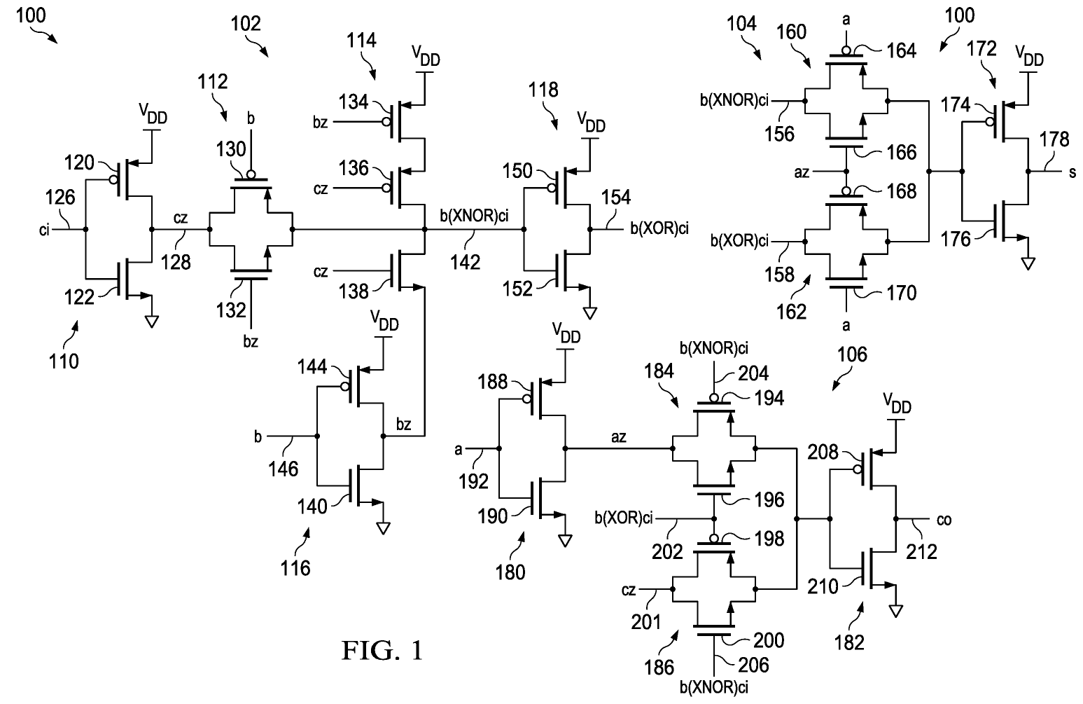

FIG. 1 is a circuit diagram of an example of a full adder 100. Full adder 100 includes a first stage 102, a second stage 104, and a third stage 106. First stage 102 comprises a first input inverter 110, a transmission gate 112, a transistor stack 114, a second input inverter 116, and an output inverter 118. Transistor stack 114 and second input inverter 116 share a transistor. First stage 102 generates intermediate signals that are reused as input signals to each of the second stage 104 and third stage 106. Second stage 104 generates and outputs a sum signal (s), and third stage 106 generates and outputs a carry-out signal (co). The sum signal (s) and the carry-out signal (co) are each generated based in part on the intermediate signals generated by first stage 102.

Referring to FIG. 1, first input inverter 110 of first stage 102 comprises a PMOS transistor 120 and an NMOS transistor 122, the drain of which is coupled to the drain of transistor 120. The source of transistor 120 is coupled to a supply voltage V_{DD}, and the source of transistor 122 is coupled to ground. The gates of transistors 120 and 122 are coupled together and form an input 126 to which a carry-in (ci) signal is applied. The common drain coupling of transistors 120 and 122 forms an intermediate output 128 at which the carry-in complement signal (cz) is generated.

Transmission gate 112 includes a PMOS transistor 130 and NMOS transistor 132 which are coupled back-to-back, and thus may be referred to as a CMOS transmission gate. Complementary control signals are applied to the gates of transistors 130 and 132 to control transmission. In the illustrated example, primary input signal (b) is applied to the gate of transistor 130, and the complement signal (bz) is applied to the gate of transistor 132. Carry-in complement signal (cz) is applied to the input of transmission gate 112. Transmission gate 112 is symmetrical or bilateral, such that the input and output are interchangeable, as are other transmission gates described herein.

Coupled to the output of transmission gate 112 is transistor stack 114 that includes two PMOS transistors 134 and 136, and two NMOS transistors 138 and 140. In the illustrated example, the source of transistor 134 is coupled to supply voltage V_{DD} and the drain of transistor 134 is coupled to the source of transistor 136. The drain of transistor 136 is coupled to the drain of transistor 138 to form an output 142 at which a first reused signal (b(XNOR)ci) is generated. The source of transistor 138 is coupled to the drain of transistor 140, the source of which is coupled to ground.

NMOS transistor 140 is shared between transistor stack 114 and second input inverter 116, which also includes a PMOS transistor 144. The source of transistor 144 is coupled to supply voltage V_{DD} and the drain of transistor 144 is coupled to the drain of shared transistor 140. The gates of transistors 140 and 144 are coupled to form an input 146 to which primary input signal (b) is applied. The output of inverter 116 (bz) is the complement of input signal (b).

Primary input compliment signal (bz) is applied to the gate of transistor 134. Carry-in input compliment signal (cz) is applied to the gates of transistors 136 and 138, and thus such gates may be coupled together to form a single input.

First reused signal (b(XNOR)ci), output from transistor stack 114, is an input to inverter 118. The output 154 of inverter 118 is (b(XOR)ci). More specifically, the input of inverter 118 is applied to the gates of PMOS transistor 150 and NMOS transistor 152. The source of transistor 150 is coupled to supply voltage V_{DD} and the source of transistor 152 is coupled to ground. The drains of transistors 150 and 152 are coupled to form an output 154 of inverter 118.

First and second reused signals are applied to inputs 156 and 158, respectively, of second stage 104 of full adder 100. Second stage 104 includes two transmission gates 160 and 162, e.g., CMOS transistor gates, each configured substantially the same as transmission gate 112. Transmission gate 160 includes a PMOS transistor 164 and an NMOS transistor 166 arranged back-to-back. Likewise, transmission gate 162 includes a back-to-back arrangement of a PMOS transistor 168 and an NMOS transistor 170. First reused signal (b(XNOR)ci) is applied to input 156 of transmission gate 160, and second reused signal (b(XOR)ci) is applied to input 158 of transmission gate 162. Transmission gates 160 and 162 are coupled together via the gates of transistors 166 and 168, which form an input to which primary input complement signal (az) is applied. Transmission gates 160 and 162 are also coupled to form a common output via the sources of transistors 164, 166, 168 and 170. Primary input signal (a) is applied to the gates of transistors 164 and 170, and thus these gates may be coupled together to form a single input.

The output of transmission gates 160 and 162 is coupled to the input of an inverter 172 of second stage 104. Inverter 172 includes a PMOS transistor 174 and an NMOS transistor 176 with their gates coupled to form the input. The sources of transistors 174 and 176 are coupled to supply voltage V_{DD} and ground, respectively. The drains of transistors 174 and 176 are coupled to form a sum output 178 at which a sum signal (s) representing a sum value is generated.

Third stage 106 forms the basis for calculating the carry-out value represented by carry-out signal (co). Third stage 106 includes two inverters, e.g., frontend inverter 180 and backend inverter 182, and a pair of transmission gates 184 and 186, e.g., CMOS transmission gates. Inverter 180 includes a PMOS transistor 188 and an NMOS transistor 190 with their gates coupled to form an input 192 to which primary input signal (a) is applied. The sources of transistors 188 and 190 are coupled to supply voltage V_{DD} and ground, respectively, and the drains of the two transistors form the output of inverter 180. The output of inverter 180, which is the primary input complement signal (az), is coupled to the input of transmission gate 184. Transmission gates 184 and 186 are coupled together at their outputs and are configured similarly to transmission gates 160 and 162. Transmission gate 184 includes a PMOS transistor 194 and an NMOS transistor 196 coupled back-to-back. Similarly, transmission gate 186 is formed by back-to-back coupling of PMOS transistor 198 and NMOS transistor 200. Carry-in complement signal (cz) is applied to input 201 of transmission gate 186. The gates of transistors 196 and 198 are coupled to form an input 202 to which the second reused signal (b(XOR)ci) is applied. The gates of transistors 194 and 200 form inputs 202 and 204, respectively, and are connected to first reused signal (b(XNOR)ci). The sources of transistors 194, 196, 198 and 200 form a common output.

Backend inverter 182 of third stage 106 is configured similarly to frontend inverter 180. That is, inverter 182 includes a PMOS transistor 208 and an NMOS transistor 210 with their gates coupled to receive the common output of transmission gates 184 and 186. The sources of transistors 208 and 210 are coupled to supply voltage V_{DD} and ground, respectively, and the drains of the two transistors form an output 212 at which carry-out signal (co) representing a carry-out value is generated.

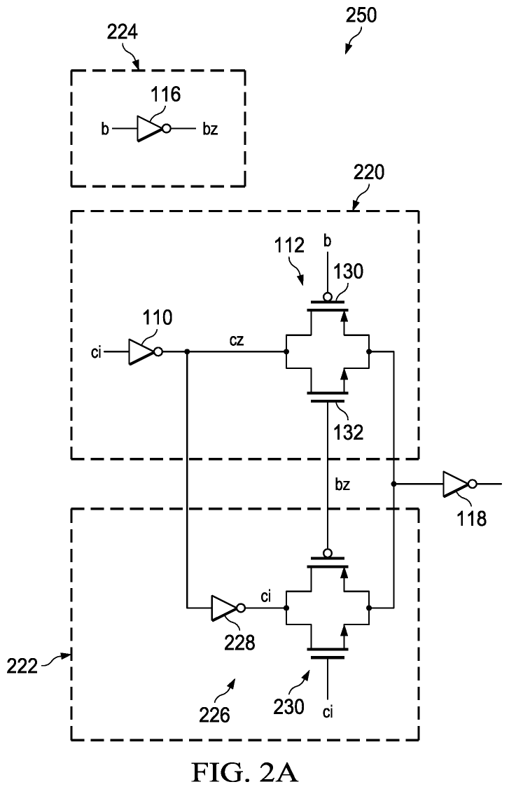

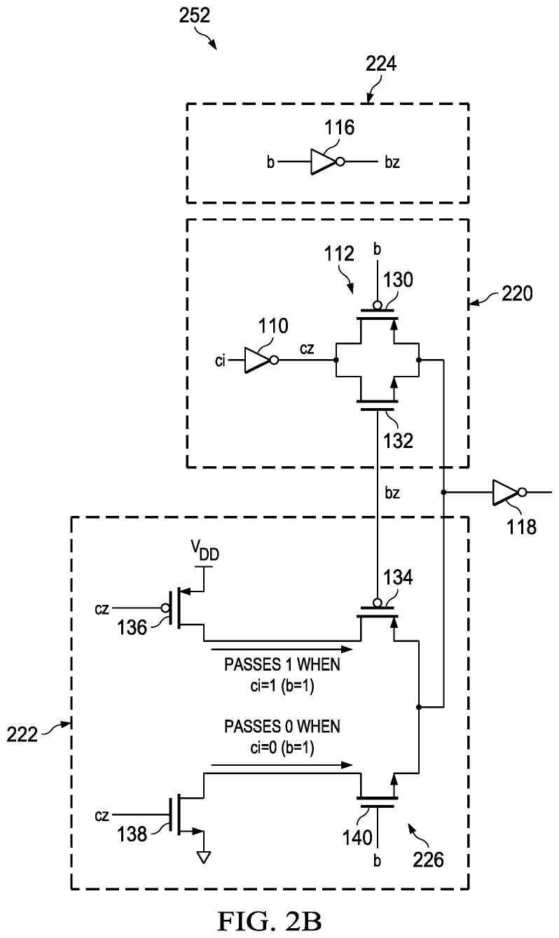

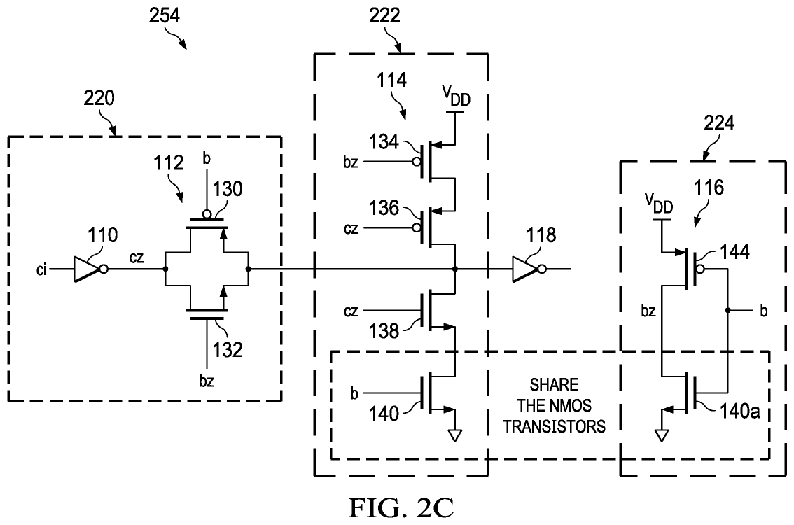

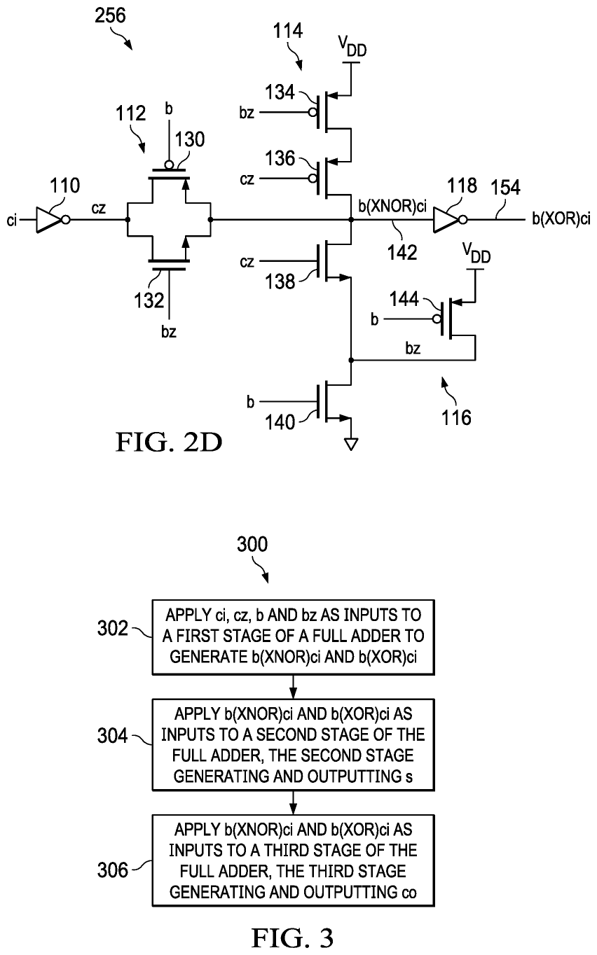

FIGS. 2A, 2B, 2C and 2D illustrate an example of forming first stage 102 of full adder 100 utilizing transistor sharing. In the illustrated example, initially, at an example first formation state 250 shown in FIG. 2A, first stage 102 comprises output inverter 118 and three components: a first component 220, a second component 222, and a third component 224. First component 220 includes first input inverter 110 and CMOS transmission gate 112. Second component 222 includes a transistor structure 226, and third component 224 includes second input inverter 116. Transistor structure 226 includes inverter 228 followed by transmission gate 230.

At an example second formation stage 252 shown in FIG. 2B, transistor structure 226 is broken down into its transistor components. PMOS transistor 136 and NMOS transistor 138 are from inverter 228, and PMOS transistor 134 and NMOS transistor 140 are from transmission gate 230. The drains of PMOS transistors 136 and 134 are coupled together to form a signal path, and the drains of NMOS transistors 138 and 140 are coupled to together to form another signal path. In an exemplary operation, logic high (i.e., 1) is passed through the path formed by transistors 136 and 134 when ci=1 and b=1, and logic low (i.e., 0) is passed through the path formed by transistors 138 and 140 when ci=0 and b=1. That is, ci is passed through one of the paths when b=1.

At an example third formation stage 254 shown in FIG. 2C, transistors 134, 136, 138 and 140 are rearranged to form transistor stack 114. In so doing, transistor 134 instead of transistor 136 is coupled to V_{DD}. At third formation stage 254, the component transistors of inverter 116 of third component 224 are shown. Inverter 116 includes PMOS transistor 144 and an NMOS transistor 140a (denoted here as such to illustrate transistor sharing between two functional components, i.e., transistor stack 114 and inverter 116).

The configuration of input stage 102 implemented with transistor sharing is present in example fourth formation stage 256, shown in FIG. 2D. That is, transistor 140 and 140a of third formation stage 254 have been merged into a single transistor 140 in fourth formation stage 256. Input stage 102 includes inverters 110 and 118 shown using the standard inverter gate symbol, as well as CMOS transmission gate 112 and transistor stack 114 shown in transistor configuration, as in FIG. 1.

FIG. 3 is a flow diagram of an example method 300 of operating or implementing a full adder, such as full adder 100. At operation 302, a carry-in signal (ci), a carry-in complement signal (cz), a first primary input signal (b), and a first primary input complement signal (bz) are applied as inputs to a first stage of a full adder to generate first and second reused signals, e.g., b(XNOR)ci and b(XOR)ci, respectively. At operation 304, the first and second reused signals are applied as inputs to a second stage of the full adder. The second stage generates and outputs a sum signal (s). At operation 306, the first and second reused signals are also applied as inputs to a third stage of the full adder. The third stage generates and outputs a carry-out signal (co). In some examples, the operation of the second and third stage at least partially overlaps.

In some examples, a second primary input signal (a) and a second primary input complement signal (az) are applied as inputs to the second stage. In some examples, second primary input signal (a), second primary input complement signal (az), and carry-in complement signal (cz) are applied as inputs to the third stage.

Various examples of compact, high performance, and low power full adders are provided. In some examples, less transistors are employed, which reduces the area that the circuit occupies and reduces the power that circuit consumes. In some examples, the transistor count is reduced by sharing a transistor among multiple functional components. In some examples, internal logic signals are reused to generate both outputs (e.g., sum (s) and carry-out (co)) to improve performance. In some examples, the number of transistors to which primary inputs (e.g., a, b and ci) are applied is reduced, which decreases the input capacitance and thus transmission delay, as well as reducing power consumption of the circuit. In an implementation, the number of transistors to which a primary input (e.g., a) is applied is reduced by 4, the number of transistors to which a primary input (e.g., b) is applied is reduced by 5, and the number of transistors to which another primary input (e.g., carry-in (ci)) is reduced by 4, relative to an existing full adder.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead. For example, a p-type metal-oxide-silicon FET (“MOSFET”) may be used in place of an n-type MOSFET with little or no changes to the circuit. Furthermore, other types of transistors may be used (such as bipolar junction transistors (BJTs)).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value.

Modifications of the described examples are possible, as are other examples, within the scope of the claims. Moreover, features described herein may be applied in other environments and applications consist with the teachings provided.

What is claimed is:

1. An adder comprising:
a first stage having a first reused signal output and a second reused signal output;
a second stage having a first reused signal input coupled to the first reused signal output, a second reused signal input coupled to the second reused signal output, and a sum signal output; and
a third stage having a third reused signal input coupled to the first reused signal output, a fourth reused signal input coupled to the second reused signal output, and a carry-out signal output.

2. The adder of claim 1, wherein a sum value represented by the sum signal and a carry-out value represented by the carry-out signal are calculated at least in part in parallel.

3. The adder of claim 1, wherein the first stage includes a transistor stack and an inverter configured to share a transistor.

4. The adder of claim 3, wherein the first stage has a carry-in input to which a carry-in signal is applied and an intermediate output at which a carry-in complement signal is generated.

5. The adder of claim 4, wherein the third stage has a carry-in complement signal input to which the carry-in complement signal is applied.

6. The adder of claim 1, wherein a carry-out value represented by the carry-out signal is calculated based on first and second values represented by first and second reused signals respectively, a first primary input value, a complement of the first primary input value, and a complement of a carry-in value.

7. The adder of claim 1, wherein a sum value represented by the sum signal (s) is calculated based on first and second values represented by first and second reused signals respectively, a first primary input value, and a complement of the first primary input value.

8. An adder comprising:
a first stage including a transistor stack and an inverter coupled to the transistor stack and configured to share a transistor, the first stage generating a plurality of signals;
a second stage coupled to the first stage and having a sum signal output, the sum signal output based in part on the plurality of signals generated in the first stage; and
a third stage coupled to the first stage and having a carry-out signal output, the carry-out signal output based in part on the plurality of signals generated in the first stage.

9. The adder of claim 8, wherein a sum value represented by the sum signal and a carry-out value represented by the carry-out signal are calculated at least in part in parallel.

10. The adder of claim 8, wherein the transistor stack has a plurality of inputs, each of which receives one of a plurality of primary input signals or complement signal thereof.

11. The adder of claim 10, wherein the plurality of input signals comprises a first primary input signal, a second primary input signal, and a carry-in input signal.

12. An adder comprising:
a first stage including:
a first component including a first inverter and a transmission gate coupled to an output of the first inverter, the transmission gate having an output,
a second component including a transistor structure coupled to the output of the first inverter and coupled to the output of the transmission gate, and
a third component including a second inverter configured to share a transistor with the transistor structure.

13. The adder of claim 12, further comprising a second stage having an output at which a sum signal is generated based in part on signals generated in the first stage.

14. The adder of claim 12, further comprising a third stage having an output at which a carry-out signal is generated based on part on signals generated in the first stage.

15. The adder of claim 12, wherein the transistor structure is arranged as a transistor stack that shares the transistor with the second inverter.

16. A method comprising:
applying a carry-in signal, a carry-in complement signal, a first primary input signal, and a first primary input complement signal as inputs to a first stage of an adder to generate first and second reused signals;
applying the first and second reused signals to a second stage of the adder, the second stage generating a sum signal; and
applying the first and second reused signals as inputs to a third stage of the adder, the third stage generating a carry-out signal.

17. The method of claim 16, wherein the second stage operates for a first time period and the third stage operates for a second time period that at least partially overlaps the first time period.

18. The method of claim 16, wherein a second primary input signal and a second primary input complement signal are applied as inputs to the second stage.

19. The method of claim 16, wherein a second primary input signal (a), a second primary input complement signal, and the carry-in complement signal are applied as inputs to the third stage.

20. A method of generating a sum signal and a carry-out signal, the method comprising:
generating, by a first stage of an adder, a first reused signal and a second reused signal in response to a carry-in input signal, a carry-in complement input signal, a first primary input signal and a first primary input complement signal;
generating, by a second stage of the adder, a sum signal in response to receiving the first reused signal and the second reused signal; and
generating, by a third stage of the adder, a carry-out signal in response to receiving the first reused signal and the second reused signal.
